(19) United States
(12) Patent Application Publication
(10) Pub. No.: US 2022/0336402 A1
(43) Pub. Date: Oct. 20, 2022

(54) SEMICONDUCTOR DEVICE, POWER CONVERSION DEVICE, AND METHOD FOR MANUFACTURING SEMICONDUCTOR DEVICE

(71) Applicant: Mitsubishi Electric Corporation, Tokyo (JP)

(72) Inventors: Haruko HITOMI, Chiyoda-ku, Tokyo (JP); Kozo HARADA, Chiyoda-ku, Tokyo (JP); Ken SAKAMOTO, Chiyoda-ku, Tokyo (JP)

(73) Assignee: Mitsubishi Electric Corporation, Tokyo (JP)

(21) Appl. No.: 17/765,439

(22) PCT Filed: Dec. 4, 2019
(86) PCT No.: PCT/JP2019/047510

§ 371 Date: Mar. 31, 2022

(51) Int. Cl. H01L 23/00

(52) U.S. Cl. CPC H01L 24/48; H01L 24/85; H01L 24/45; H01L 2224/85345; H01L 2224/4807; H01L 2224/48235; H01L 2224/48992; H01L 2224/4556; H01L 2224/45691; H01L 2224/4555; H01L 2224/4501; H01L 2924/3512; H01L 2924/0695; H01L 2924/07025; H01L 2224/85007; H01L 2924/182; H01L 2924/172; H01L 2924/173; H01L 2924/17724

(57) ABSTRACT

A semiconductor device includes a semiconductor element, at least one first resin member, and at least one conducting wire. The semiconductor element includes a front electrode and a body part. The at least one first resin member is disposed on a second surface of the front electrode. The at least one conducting wire includes a joining part. The at least one first resin member includes a convex part. The convex part protrudes from the front electrode in a direction away from the body part. The at least one conducting wire includes a concave part. The concave part is adjacent to the joining part. The concave part extends along the convex part. The concave part is fitted to the convex part.

### TECHNICAL FIELD

The present invention relates to a semiconductor device, a power conversion device, and a method for manufacturing a semiconductor device.

### BACKGROUND ART

A known semiconductor device includes a semiconductor element, a conducting wire bonded to an electrode of the semiconductor element at a joining part, and a first resin member covering the joining part of the conducting wire and the electrode. For example, the semiconductor device disclosed in WO 2016/016970 (PTL 1) allows the first resin member disposed on the electrode to spread out to an end of the joining part of the conducting wire.

### CITATION LIST

### Patent Literature

PTL 1: WO2016/016970

### SUMMARY OF INVENTION

### Technical Problem

In the semiconductor device disclosed in PTL 1, the viscosity of the first resin member is low enough to allow the first resin member to flow on the electrode. It is therefore required that, in order to prevent the first resin member from flowing out from above the electrode, a second resin film thicker than the first resin member be further provided on the periphery of the electrode. This makes the structure of the semiconductor device complicated.

The present invention has been made in view of the above-described problems, and it is therefore an object of the present invention to provide a semiconductor device, a power conversion device, and a method for manufacturing a semiconductor device, the semiconductor device allowing a first resin member to spread out to an end of a joining part of a conducting wire between the conducting wire and an electrode and having a simple structure.

### Solution to Problem

A semiconductor device according to the present invention includes a semiconductor element, at least one first resin member, and at least one conducting wire. The semiconductor element includes a body part and a front electrode. The front electrode has a first surface and a second surface. The first surface is bonded to the body part. The second surface is positioned on an opposite side of the first surface. The at least one first resin member is disposed on the second surface of the front electrode. The at least one conducting wire includes a joining part. The joining part is adjacent to the at least one first resin member. The joining part is bonded to the second surface. The at least one first resin member includes a convex part. The convex part protrudes from the front electrode in a direction away from the body part. The at least one conducting wire includes a concave part. The concave part is adjacent to the joining part. The concave part extends along the convex part. The concave part is fitted to the convex part.

### Advantageous Effects of Invention

In the semiconductor device according to the present invention, the concave part of the at least one conducting wire is adjacent to the joining part. The concave part is fitted to the convex part of the at least one first resin member. This allows the convex part of the first resin member to spread out to an end of the joining part. Further, the concave part of the at least one conducting wire is fitted to the convex part of a first resin part. This makes it possible to provide a semiconductor device having a simple structure.

### BRIEF DESCRIPTION OF DRAWINGS

FIG. 1 is a schematic cross-sectional view of a configuration of a semiconductor device according to a first embodiment.

FIG. 2 is an enlarged top view of an area II illustrated in FIG. 1, schematically illustrating the configuration of the semiconductor device according to the first embodiment.

FIG. 3 is an enlarged cross-sectional view of the area II illustrated in FIG. 1, schematically illustrating the configuration of the semiconductor device according to the first embodiment.

FIG. 4 is an enlarged cross-sectional view corresponding to FIG. 3, illustrating dimensions of a first resin member and a conducting wire.

FIG. 5 is an enlarged cross-sectional view of the area II illustrated in FIG. 1, schematically illustrating a different configuration of the semiconductor device according to the first embodiment.

FIG. 6 is a cross-sectional view taken along a line VI-VI in FIG. 3.

FIG. 7 is a cross-sectional view taken along a line VII-VII in FIG. 3.

FIG. 8 is a cross-sectional view taken along a line VIII-VIII in FIG. 3.

FIG. 9 is a cross-sectional view taken along a line IX-IX in FIG. 3.

FIG. 10 is an enlarged top view corresponding to the area II illustrated in FIG. 1, schematically illustrating a configuration of a semiconductor device according to a first modification of the first embodiment.

FIG. 11 is an enlarged top view corresponding to the area II illustrated in FIG. 1, schematically illustrating a configuration of a semiconductor device according to a second modification of the first embodiment.

FIG. 12 is an enlarged cross-sectional view corresponding to the area II illustrated in FIG. 1, schematically illustrating the configuration of the semiconductor device according to the second modification of the first embodiment.

FIG. 13 is a flowchart schematically illustrating a method for manufacturing a semiconductor device according to the first embodiment.

FIG. 14 is a schematic cross-sectional view of a first resin member and a first electrode during the execution of the method for manufacturing a semiconductor device according to the first embodiment.

FIG. 15 is a schematic cross-sectional view of a dispenser, the first resin member, and the first electrode during the execution of the method for manufacturing a semiconductor device according to the first embodiment.

FIG. 16 is a flowchart schematically illustrating a different method for manufacturing a semiconductor device according to the first embodiment.

FIG. 17 is a schematic cross-sectional view of a configuration of a semiconductor device according to a second embodiment.

FIG. 18 is an enlarged cross-sectional view of an area XVIII illustrated in FIG. 17, schematically illustrating the configuration of the semiconductor device according to the second embodiment.

FIG. 19 is an enlarged top view of the area XVIII illustrated in FIG. 17, schematically illustrating the configuration of the semiconductor device according to the second embodiment.

FIG. 20 is an enlarged top view corresponding to FIG. 19, schematically illustrating a configuration of a semiconductor device according to a modification of the second embodiment.

FIG. 21 is a flowchart schematically illustrating a method for manufacturing a semiconductor device according to the second embodiment.

FIG. 22 is a block diagram schematically illustrating a configuration of a power conversion system according to a third embodiment.

### DESCRIPTION OF EMBODIMENTS

Hereinafter, embodiments will be described with reference to the drawings. Note that, in the following description, the same or corresponding parts are denoted by the same reference numerals, and no redundant description will be given of such parts.

### First Embodiment

<Configuration of Semiconductor Device 50>

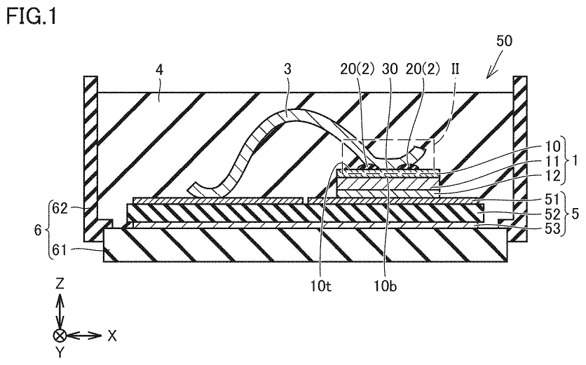

With reference to FIG. 1, a description will be given of a configuration of a semiconductor device 50 according to a first embodiment. As illustrated in FIG. 1, semiconductor device 50 includes a semiconductor element 1, at least one first resin member 2, at least one conducting wire 3, a circuit board 5, and a case 6. Semiconductor device 50 may include a sealing resin member 4. Semiconductor device 50 is a power semiconductor device used in power electronics.

<Configuration of Semiconductor Element 1>

With reference to FIG. 1, a description will be given below of a configuration of semiconductor element 1 according to the first embodiment. As illustrated in FIG. 1, semiconductor element 1 includes a front electrode 10, a body part 11, and a back electrode 12. Front electrode 10 has a first surface 10b and a second surface 10t. First surface 10b is bonded to body part 11. Second surface 10t is positioned on an opposite side of first surface 10b. According to the present embodiment, a direction in which first surface 10b and second surface 10t are positioned on opposite sides of front electrode 10 is defined as a first direction (Z-axis direction).

Semiconductor element 1 is a power semiconductor element used in power electronics. Examples of semiconductor element 1 include switching elements such as an insulated gate bipolar transistor (IGBT) and a metal oxide semiconductor field effect transistor (MOSFET), and a rectifier such as a Schottky barrier diode. Semiconductor element 1 is made of, for example, silicon (Si). Examples of the material of semiconductor element 1 include a wide band gap semiconductor material such as silicon carbide (SiC), gallium nitride (GaN), and diamond.

At least one conducting wire 3 is bonded to front electrode 10. Second surface 10t of front electrode 10 faces at least one conducting wire 3. Back electrode 12 is bonded to circuit board 5. Body part 11 is interposed between front electrode 10 and back electrode 12.

Front electrode 10 and back electrode 12 are each made of, for example, an aluminum (Al) alloy containing silicon (Si). Front electrode 10 and back electrode 12 may be covered with at least one coating layer (not illustrated). The at least one coating layer (not illustrated) is made of, for example, nickel (Ni) or gold (Au). The at least one coating layer (not illustrated) may include a plurality of coating layers (not illustrated). The plurality of coating layers (not illustrated) may be stacked on top of each other.

<Configuration of First Resin Member 2>

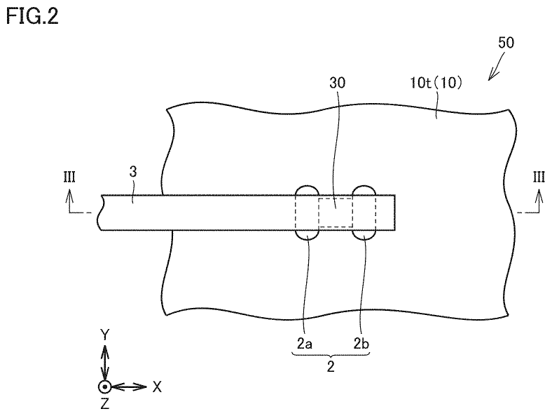

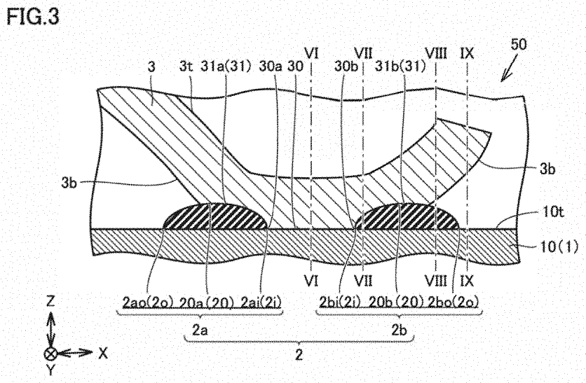

With reference to FIGS. 1 to 5, a description will be given below of a configuration of first resin member 2 according to the first embodiment. Note that scaling resin member 4 (see FIG. 1) is not illustrated in FIGS. 2 to 5 for the sake of simplicity. As illustrated in FIG. 1, at least one first resin member 2 is disposed on second surface 10t of front electrode 10. As illustrated in FIG. 2, at least one first resin member 2 intersects with at least one conducting wire 3 in atop view. As illustrated in FIG. 3, each of at least one first resin member 2 has a curved-mountain shape as viewed in a third direction (Y-axis direction). At least one first resin member 2 is disposed between second surface 10t of front electrode 10 and at least one conducting wire 3.

As illustrated in FIG. 3, at least one first resin member 2 includes a convex part 20. Convex part 20 protrudes from front electrode 10 in a direction away from body part 11. Convex part 20 is a convex surface extending along a concave part 31 (to be described later). Convex part 20 includes a convex part inner end 2i and a convex part outer end 2a. Convex part inner end 2i is adjacent to a joining part 30 (to be described later) and concave part 31. Convex part outer end 20 is provided opposite to joining part 30, with respect to convex part inner end 2i in between.

As illustrated in FIG. 3, according to the present embodiment, at least one first resin member 2 includes one first resin member 2a and an other first resin member 2b. One first resin member 2a is disposed away from other first resin member 2b. One first resin member 2a includes one convex part 20a belonging to convex part 20. One convex part 20a includes one convex part inner end 2ai belonging to convex part inner end 2i and one convex part outer end 2ao belonging to convex part outer end 2o.

Other first resin member 2b includes an other convex part 20b belonging to convex part 20. Other convex part 20b includes an other convex part inner end 2bi included in convex part inner end 2i and an other convex part outer end 2bo included in convex part outer end 2o.

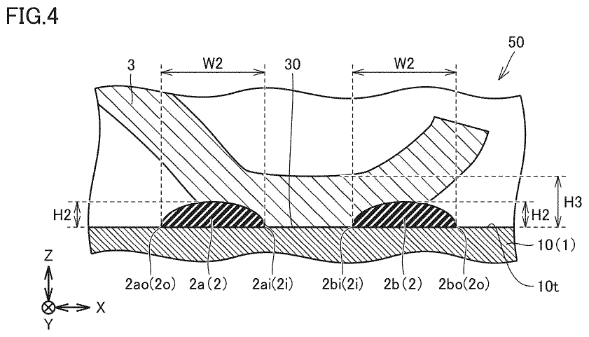

As illustrated in FIG. 4, a dimension H2 of at least one first resin member 2 in the first direction (Z-axis direction) is, for example, 0.2 times or more and less than 1 time a dimension H3 of at least one conducting wire 3 in the first direction (Z-axis direction) at a portion where joining part 30 is provided. The dimension of each of at least one first resin member 2 in the first direction (Z-axis direction) is a dimension from second surface 10t of front electrode 10 to the top of convex part 20.

A dimension W2 of at least one first resin member 2 in a second direction (X-axis direction) is, for example, 0.5 times or more and 10 times or less a dimension of joining part 30 in the third direction (Y-axis direction). The dimension of first resin member 2 in the second direction (X-axis direction) is a dimension from convex part inner end 2i to convex part outer end 2o of convex part 20.

Each of at least one first resin member 2 contains at least either a polyimide-based resin or a polyamide-based resin. At least one first resin member 2 is made of a resin having high heat resistance.

At least one first resin member 2 has a viscosity of greater than or equal to 50 Pa·s and less than or equal to 150 Pa·s, for example. According to the present embodiment, the viscosity is measured by a cone and plate method defined in JIS5600-2-3.

At least one first resin member 2 has a thixotropy index of greater than or equal to 1.1, for example. The thixotropy index of at least one first resin member 2 may be greater than or equal to 2.5, for example. According to the present embodiment, the thixotropy index corresponds to a thixotropy index defined in JISK6833-1.

First resin member 2 may have a glass transition temperature higher than the maximum allowable working temperature of semiconductor device 50. The glass transition temperature of first resin member 2 may be greater than or equal to 150° C., for example. First resin member 2 may contain a filler (not illustrated). The filler (not illustrated) contained in first resin member 2 is made of, for example, metal or rubber.

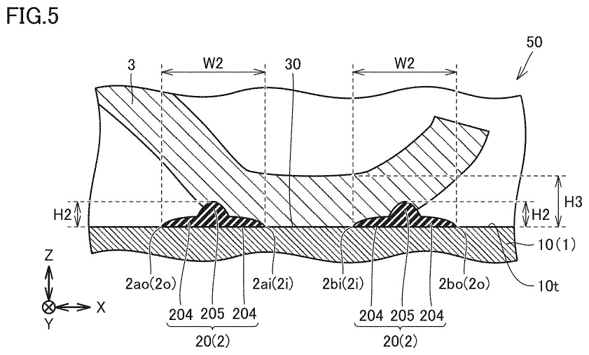

As illustrated in FIG. 5, convex part 20 may include a projecting edge 204 and a protrusion 205. Projecting edge 204 is in contact with second surface 10t. Protrusion 205 protrudes from projecting edge 204 in a direction away from second surface 10t. When convex part 20 includes projecting edge 204 and protrusion 205, a dimension of convex part 20 in the first direction (Z-axis direction) is a dimension from second surface 10t to the top of convex part 20.

<Configuration of Conducting Wire 3>

With reference to FIGS. 3 to 9, a description will be given below of a configuration of conducting wire 3 according to the first embodiment. Note that scaling resin member 4 (see FIG. 1) is not illustrated in FIGS. 3 to 9 for the sake of simplicity. As illustrated in FIG. 3, at least one conducting wire 3 includes joining part 30. Joining part 30 is adjacent to at least one first resin member 2. Joining part 30 is bonded to second surface 10t. At least one conducting wire 3 includes concave part 31. Concave part 31 is adjacent to joining part 30. Concave part 31 extends along convex part 20. Concave part 31 is fitted to convex part 20.

According to the present embodiment, a direction in which joining part 30 extends toward concave part 31 along second surface 10t is defined as the second direction (X-axis direction). The second direction (X-axis direction) is the same as a longitudinal direction of joining part 30. A direction orthogonal to both the first direction (Z-axis direction) and the second direction (X-axis direction) is defined as the third direction (Y-axis direction). The third direction (Y-axis direction) is the same as a width direction of joining part 30.

As illustrated in FIG. 3, joining part 30 is interposed between one convex part 20a and other convex part 20b along second surface 10t. Joining part 30 includes a joining part one end 30a and a joining part other end 30b. Joining part one end 30a is adjacent to one convex part inner end 2ai. Joining part other end 30b is adjacent to other convex part inner end 2bi. A dimension of joining pan 30 in the second direction (X-axis direction) is a dimension from joining part one end 30a to joining part other end 30b along second surface 10t of front electrode 10.

According to the present embodiment, joining part 30 is in contact with first resin member 2 only at joining part one end 30a and joining part other end 30b. Joining part 30 is not surrounded by first resin member 2. Joining part one end 30a is in contact with one first resin member 2a extending from a joining part one end 30a side toward joining part other end 30b. Joining part other end 30b is in contact with other first resin member 2b extending from a joining part other end 30b side toward joining part one end 30a.

As illustrated in FIG. 3, concave part 31 is adjacent to convex part 20 and joining part 30. Concave part 31 is a concave surface extending along convex part 20. Concave part 31 overlaps convex part 20 in a top view. According to the present embodiment, concave part 31 includes one concave part 31a and an other concave part 31b. Joining part 30 is interposed between one concave part 31a and other concave part 31b. One concave part 31a is fitted to one convex part 20a of one first resin member 2a. One concave part 31a is adjacent to joining part 30 and one first resin member 2a at joining part one end 30a. Other concave part 31b is fitted to other convex part 20b of other first resin member 2b. Other concave part 31b is adjacent to joining part 30 and other first resin member 2b at joining part other end 30b.

As illustrated in FIG. 1, at least one conducting wire 3 is bonded to a conducting circuit pattern 51 of circuit board 5. At least one conducting wire 3 may be bonded to front electrode 10 and conducting circuit pattern 51, for example, by means of a wire bonder.

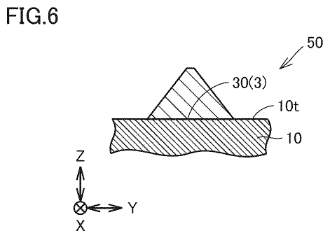

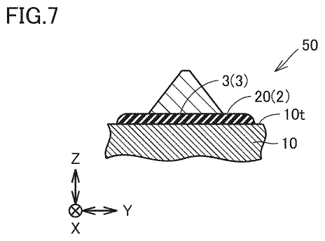

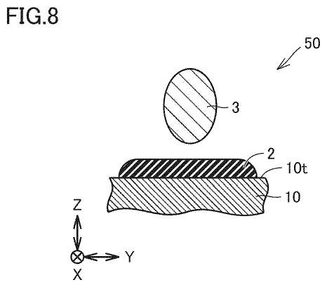

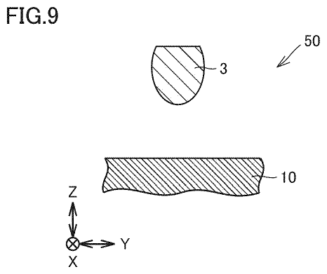

At least one conducting wire 3 is bonded, for example, by means of a wedge tool. As illustrated in FIG. 6, when at least one conducting wire 3 is bonded by means of the wedge tool, a cross-sectional shape of joining part 30 becomes nearly triangular. As illustrated in FIG. 7, when at least one conducting wire 3 is bonded by means of the wedge tool, a cross-sectional shape of concave part 31 become nearly triangular. As illustrated in FIGS. 8 and 9, an extending part extending from concave part 31 in a direction away from joining part 30 is distanced from second surface 10t and at least one first resin member 2.

As illustrated in FIG. 3, at least one conducting wire 3 includes a wire upper surface 3t and a wire lower surface 3b. Wire lower surface 3b faces second surface 10t of front electrode 10. Wire upper surface 3t is positioned on an opposite side of wire lower surface 3b.

At least one conducting wire 3 is made of, for example, metal such as gold (Au), aluminum (Al), or copper (Cu).

<Configuration of Sealing Resin Member 4>

With reference to FIG. 1, a description will be given below of a configuration of scaling resin member 4 according to the first embodiment. As illustrated in FIG. 1, scaling resin member 4 has semiconductor element 1, at least one first resin member 2, and at least one conducting wire 3 encapsulated therein. Sealing resin member 4 may have at least some of conducting wire 3 or the whole of conducting wire 3 encapsulated therein. Scaling resin member 4 is made of, for example, an insulating resin material.

Semiconductor device 50 may include sealing resin member 4 or need not include sealing resin member 4.

<Configuration of Circuit Board 5>

With reference to FIG. 1, a description will be given below of a configuration of circuit board 5 according to the first embodiment. As illustrated in FIG. 1, circuit board 5 includes conducting circuit pattern 51, an insulating substrate 52, and a conducting plate 53. Conducting circuit pattern 51, insulating substrate 52, and conducting plate 53 are stacked in this order. Insulating substrate 52 extends in an X-Y plane. Insulating substrate 52 is made of, for example, an inorganic material (ceramic material) such as aluminum oxide (Al₂O₃), aluminum nitride (AlN), or silicon nitride (Si₃N₄). Insulating substrate 52 includes an insulating substrate upper surface and an insulating substrate lower surface on a side opposite to insulating substrate upper surface. Conducting circuit pattern 51 is provided on the insulating substrate upper surface. Conducting plate 53 is provided on the insulating substrate lower surface. Conducting circuit pattern 51 and conducting plate 53 are made of, for example, metal such as copper (Cu) or aluminum (Al).

Back electrode 12 of semiconductor element 1 is bonded to conducting circuit pattern 51. Back electrode 12 is bonded to conducting circuit pattern 51 by means of, for example, solder or a metal particulate sintered body (not illustrated).

<Case 6>

With reference to FIG. 1, a description will be given below of a configuration of case 6 according to the first embodiment. As illustrated in FIG. 1, case 6 includes a heat sink 61 and an enclosure 62. Semiconductor device 50 is structured as a case type module by case 6. An inner space of case 6 is filled at least in part with scaling resin member 4.

Circuit board 5 is attached to heat sink 61. Conducting plate 53 of circuit board 5 is bonded to heat sink 61 by means of a bonding member (not illustrated) such as electrothermal grease. Heat generated by semiconductor element 1 is transferred to heat sink 61 through circuit board 5. The heat transferred to heat sink 61 is dissipated away from semiconductor device 50. Heat sink 61 is made of, for example, metal such as aluminum (Al).

Enclosure 62 surrounds semiconductor element 1, at least one first resin member 2, at least one conducting wire 3, circuit board 5, and scaling resin member 4. Enclosure 62 is attached to a periphery of heat sink 61. Enclosure 62 is made of, for example, an insulating resin such as polyphenylene sulfide (PPS) or polybutylene terephthalate (PBT).

<Configuration of First Modification>

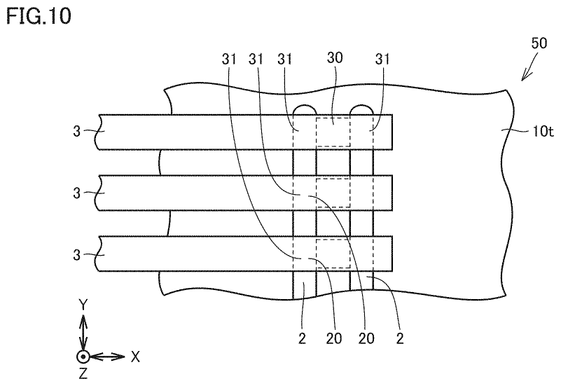

Hereinafter, a first modification of the first embodiment will be described with reference to FIG. 10. Note that, in the following description, the same or corresponding parts are denoted by the same reference numerals, and no redundant description will be given of such parts.

As illustrated in FIG. 10, according to the first modification of the first embodiment, at least one conducting wire 3 includes a plurality of conducting wires 3. Concave part 31 of each of plurality of conducting wires 3 is fitted to convex part 20. According to the present embodiment, at least one first resin member 2 extends over plurality of conducting wires 3. Each of at least one first resin member 2 intersects with plurality of conducting wires 3. The first modification of the first embodiment is different from the first embodiment in that at least one conducting wire 3 according to the modification of the first embodiment includes plurality of conducting wires 3.

<Configuration of Second Modification>

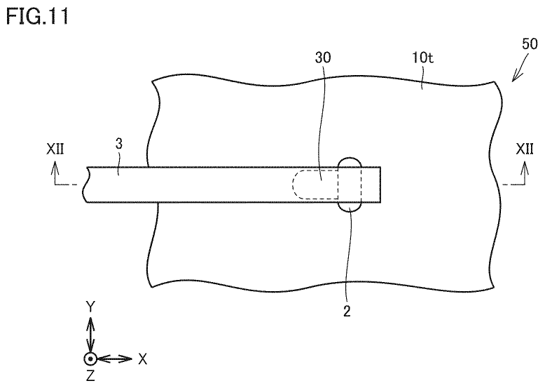

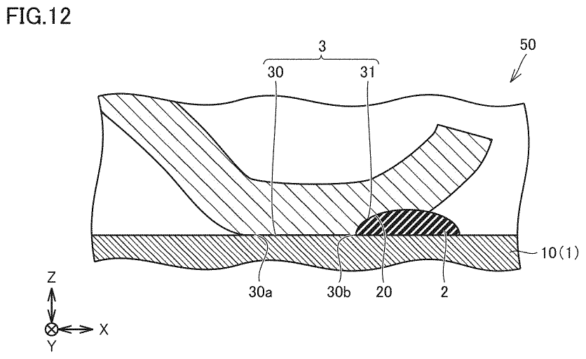

Hereinafter, a second modification of the first embodiment will be described with reference to FIGS. 11 and 12. Note that, in the following description, the same or corresponding parts are denoted by the same reference numerals, and no redundant description will be given of such parts.

As illustrated in FIG. 11, according to the second modification of the first embodiment, at least one first resin member 2 is made up of one first resin member 2. At least one conducting wire 3 is made up of one conducting wire 3. As illustrated in FIG. 12, convex part 20 of one first resin member 2 is fitted to one concave pan 31 of one conducting wire 3. Convex part 20 is in contact with either joining part one end 30a or joining part other end 30b of joining part 30.

### <Method for Manufacturing Semiconductor Device 50>

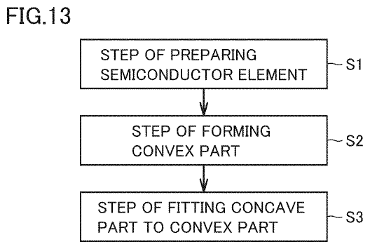

Next, a method for manufacturing semiconductor device 50 according to the first embodiment will be described mainly with reference to FIG. 13 to 16.

As illustrated in FIG. 13, the method for manufacturing semiconductor device 50 includes step S1 of preparing semiconductor element 1, step S2 of forming convex part 20, and step S3 of fitting concave part 31 to convex part 20.

In step S1 of preparing semiconductor element 1, semiconductor element 1 is prepared. As illustrated in FIG. 1, semiconductor element 1 is bonded to circuit board 5.

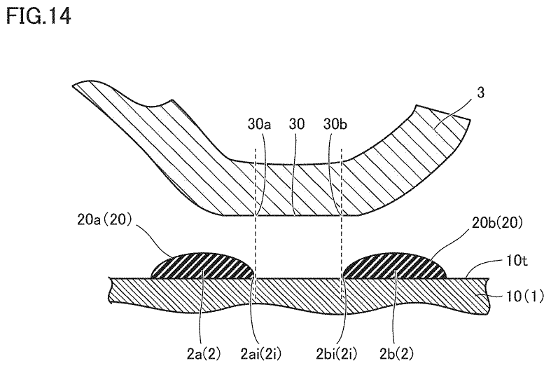

As illustrated in FIG. 14, in step S2 of forming convex part 20, applying at least one first resin member 2 to second surface 10t of front electrode 10 forms convex part 20 on at least one first resin member 2.

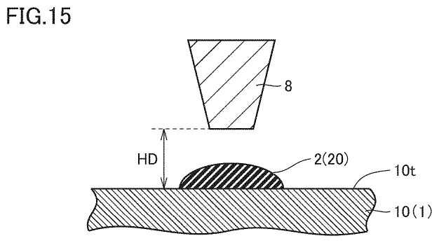

As illustrated in FIG. 15, first resin member 2 is applied to front electrode 10 by means of a dispenser 8. When first resin member 2 has a thixotropy index of greater than 1.1, a distance HD between front electrode 10 and a dispenser nozzle at the time of dispensing first resin member 2 is less than distance HD when first resin member has a thixotropy index of less than or equal to 1.1.

As illustrated in FIG. 14, first resin member 2 is applied in advance such that convex part 20 is disposed adjacent to at least either joining part one end 30a or joining part other end 30b in step S3 of fitting concave part 31 (see FIG. 3) to convex part 20. Specifically, first resin member 2 is applied in advance such that one convex part 20a is disposed adjacent to joining part one end 30a in step S3 of fitting concave part 31 (see FIG. 3) to convex part 20. Specifically, first resin member 2 is applied in advance such that other convex part 20b is disposed adjacent to joining part other end 30b in step S3 of fitting concave part 31 (see FIG. 3) to convex part 20.

First resin member 2 thus applied is heated. Heating first resin member 2 evaporates a solvent contained in first resin member 2, so that first resin member 2 hardens enough to keep the shape of convex part 20 when conducting wire 3 is bonded. According to the present embodiment, a case where first resin member 2 hardens enough to keep the shape of the convex part 20 when conducting wire 3 is bonded is referred to as temporary hardening.

In step S2 of forming convex part 20, at least one first resin member 2 is temporarily hardened so as to keep convex part 20 of at least one first resin member 2. For example, first resin member 2 is temporarily hardened by being heated at 100° C. for 1 minute on a hot plate. As illustrated in FIG. 14, first resin member 2 thus temporarily hardened can be bonded to conducting wire 3.

As illustrated in FIG. 3, in step S3 of fitting concave part 31 to convex part 20, joining part 30 of the at least one conducting wire 3 is bonded to second surface 10t of front electrode 10 so as to be adjacent to at least one first resin member 2. In step S3 of fitting concave part 31 to convex part 20, concave part 31 is formed and fitted to convex part 20. When conducting wire 3 is deformed along convex part 20, concave part 31 is formed in conducting wire 3. Specifically, when conducting wire 3 is pressed against first resin member 2 temporarily hardened, conducting wire 3 is dented, so that concave part 31 is formed in conducting wire 3. After first resin member 2 is applied to second surface 10t of front electrode 10, conducting wire 3 is bonded to second surface 10t, and concave part 31 is fitted to convex part 20.

Further, in step S3 of fitting concave part 31 to convex part 20, circuit board 5 is bonded to heat sink 61. Enclosure 62 is bonded to heat sink 61.

After step S3 of fitting concave part 31 to convex part 20, first resin member 2 is fully hardened. When the solvent of first resin member 2 is sufficiently volatilized, first resin member 2 is fully hardened. When first resin member 2 contains a polyimide-based resin, a ring closure reaction occurs in the imide precursor, so that first resin member 2 is fully hardened. In order to fully harden first resin member 2, first resin member 2 is heated, for example, at 200° C. for 3 hours in a low oxygen oven.

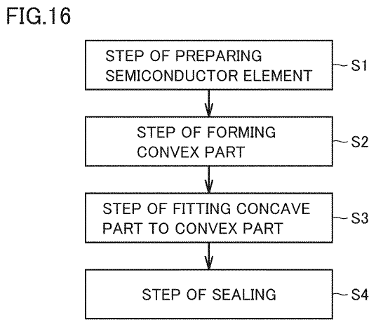

As illustrated in FIG. 16, the method for manufacturing semiconductor device 50 may include step S4 of scaling semiconductor element 1, at least one first resin member 2, and conducting wire 3 in sealing resin member 4 after step S3 of fitting concave part 31 to convex part 20. Scaling resin member 4 in a liquefied state is supplied onto semiconductor element 1, at least one first resin member 2, and conducting wire 3. Sealing resin member 4 thus supplied is hardened.

<Actions and Effects>

Next, actions and effects of the present embodiment will be described.

In semiconductor device 50 according to the present embodiment, as illustrated in FIG. 3, concave part 31 of at least one conducting wire 3 is adjacent to joining part 30 and is thus in contact with the end of joining part 30. Concave part 31 is fitted to convex part 20 of at least one first resin member 2. This allows convex part 20 of first resin member 2 fitted to concave part 31 to spread out to an end of joining part 30.

Specifically, one first resin member 2a can be disposed adjacent to one concave part 31a and joining part one end 30a of at least one conducting wire 3. This allows one first resin member 2a to spread out to joining part one end 30a. Further, other first resin member 2b can be disposed adjacent to other concave part 31b and joining part other end 30b of at least one conducting wire 3. This allows other first resin member 2b to spread out to joining part other end 30b.

As illustrated in FIG. 3, since at least one concave part 31 is fitted to convex part 20 of at least one first resin member 2, first resin member 2 can be provided between front electrode 10 and conducting wire 3 without a gap. This allows the shape of first resin member 2 to be stable. Accordingly, even when semiconductor device 50 is certified during a power cycle test, first resin member 2 can be continuously held between at least one conducting wire 3 and front electrode 10. This makes it possible to prevent joining part 30 from cracking. This in turn makes it possible to increase the reliability of semiconductor device 50.

As illustrated in FIG. 3, concave part 31 of at least one conducting wire 3 is fitted to convex part 20 of first resin member 2. First resin member 2 is fitted to concave part 31 with convex part 20 maintained. This makes it possible to provide semiconductor device 50 having a simple structure.

Since first resin member 2 has a viscosity of greater than or equal to 50 Pa·s and less than or equal to 150 Pa·s, first resin member 2 can be held on front electrode 10. As a result, there is no possibility that first resin member 2 flows out from above front electrode 10. This eliminates the need of providing a structure for preventing first resin member 2 from flowing out from above front electrode 10. This in turn makes it possible to provide semiconductor device 50 having a simple structure.

Since first resin member 2 contains at least either a polyimide-based resin or a polyamide-based resin, first resin member 2 is higher in heat resistance than first resin member 2 containing neither the polyimide-based resin nor the polyamide-based resin. This makes it possible to provide semiconductor device 50 having high reliability.

As illustrated in FIG. 4, dimension H2 of at least one first resin member 2 in the first direction (Z-axis direction) is 0.2 times or more and less than 1 time dimension H3 of at least one conducting wire 3 in the first direction (Z-axis direction) at the portion where joining part 30 is provided, and dimension W2 of at least one first resin member 2 in the second direction (X-axis direction) is 0.5 times or more and 10 times or less the dimension of joining part 30 in the third direction (Y-axis direction). This allows at least one first resin member 2 to be efficiently disposed between at least one conducting wire 3 and front electrode 10. Specifically, first resin member 2 can be disposed between conducting wire 3 and front electrode 10 with first resin member 2 prevented from protruding from between conducting wire 3 and front electrode 10. This allows a reduction in the usage of first resin member 2. In addition, efficiently providing first resin member 2 allows conducting wire 3 to be efficiently reinforced by first resin member 2.

If first resin member 2 fills a space between conducting wire 3 and front electrode 10 due to the surface tension of first resin member 2, it is difficult to set the dimension of first resin member 2 equal to the above-described dimension, which makes it difficult to efficiently provide first resin member 2.

Since first resin member 2 has a thixotropy index of greater than or equal to 1.1, dimension 142 of at least one first resin member 2 in the first direction (Z-axis direction) can be 0.2 times or more and less than 1 time dimension H3 of at least one conducting wire 3 in the first direction (Z-axis direction) at the portion where joining part 30 is provided, and dimension W2 of at least one first resin member 2 in the second direction (X-axis direction) can be 0.5 times or more and 10 times or less the dimension of joining part 30 in the third direction (Y-axis direction). This allows first resin member 2 to be efficiently provided.

As illustrated in FIG. 3, joining part 30 is in contact with first resin member 2 only at joining part one end 30a and joining part other end 30b. The usage of first resin member 2 can be reduced as compared with a case where the entire periphery of joining part 30 is in contact with first resin member 2.

According to the first modification of the present embodiment, as illustrated in FIG. 10, concave part 31 of each of plurality of conducting wires 3 is fitted to convex part 20. This causes plurality of conducting wires 3 to be bonded to each first resin member 2. Therefore, a working time taken for manufacturing semiconductor device 50 can be shortened as compared with a case where plurality of first resin members 2 are dispensed.

According to the second modification of the present embodiment, as illustrated in FIG. 12, at least one first resin member 2 may be made of one first resin member 2. This allows a reduction in the usage of first resin member 2 as compared with a case where at least one first resin member 2 includes plurality of first resin members 2. This in turn allows a reduction in the manufacturing cost of semiconductor device 50.

The method for manufacturing semiconductor device 50 according to the present embodiment includes, as illustrated in FIG. 13, step S3 of fitting concave part 31 of conducting wire 3 to convex part 20 of first resin member 2. This allows first resin member 2 to be disposed between conducting wire 3 and front electrode 10 without a gap.

The method for manufacturing semiconductor device 50 includes step S3 of fitting concave part 31 of conducting wire 3 to convex part 20 of first resin member 2. This causes first resin member 2 to be fitted to concave part 31 with convex part 20 maintained. This in turn makes it possible to provide semiconductor device 50 having a simple structure.

After first resin member 2 is applied to second surface 10t of front electrode 10, concave part 31 of conducting wire 3 is bonded to convex part 20 of first resin member 2, so that first resin member 2 can be disposed between conducting wire 3 and front electrode 10 without a gap.

In step S2 of forming convex part 20, at least one first resin member 2 is temporarily hardened so as to keep convex part 20 of at least one first resin member 2. This allows the shape of convex part 20 to be kept. Further, when at least one conducting wire 3 is pressed against at least one first resin member 2 thus temporarily hardened, at least one conducting wire 3 is dented. This allows concave part 31 to be formed in at least one conducting wire 3.

After step S3 of fitting concave part 31 to convex part 20, first resin member 2 is fully hardened. This allows first resin member 2 to sufficiently adhere to conducting wire 3.

As illustrated in FIG. 16, semiconductor element 1, at least one first resin member 2, and conducting wire 3 are encapsulated in sealing resin member 4 after step S3 of fitting concave part 31 to convex part 20. This causes semiconductor element 1, at least one first resin member 2, and conducting wire 3 to be reinforced by scaling resin member 4, allowing an increase in the reliability of semiconductor device 50.

### Second Embodiment

A second embodiment is the same in configuration, manufacturing method, and actions and effects as the first embodiment unless otherwise specified. Therefore, the same components as the components according to the first embodiment are denoted by the same reference numerals, and no description will be given below of such components.

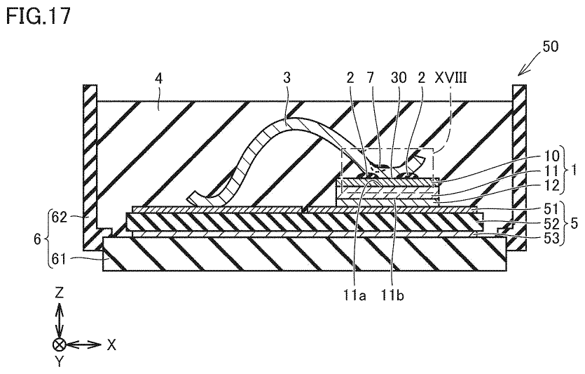

With reference to FIGS. 17 to 19, a description will be given of a configuration of a semiconductor device 50 according to the second embodiment. As illustrated in FIG. 17, according to the present embodiment, semiconductor device 50 further includes a second resin member 7. Semiconductor device 50 according to the present embodiment is different from semiconductor device 50 according to the first embodiment in that second resin member 7 is further provided.

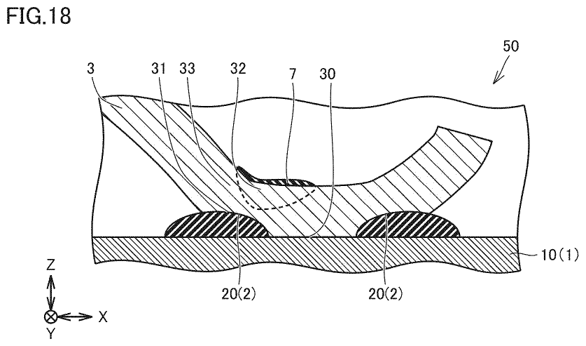

As illustrated in FIG. 18, according to the present embodiment, at least one conducting wire 3 includes an adjacent part 32 and a rising part 33. Adjacent part 32 is adjacent to joining part 30. Rising part 33 rises from adjacent part 32 on front electrode 10 in a direction away from body part 11 (see FIG. 1). At least one conducting wire 3 is bent at joining part 30, adjacent part 32, and rising part 33. Joining part 30, adjacent part 32, and rising part 33 constitute a neck pan of at least one conducting wire 3.

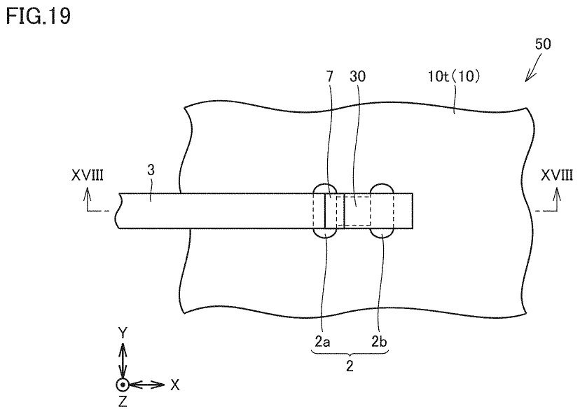

Second resin member 7 covers a portion extending from rising part 33 to joining part 30 through adjacent part 32 on a side of at least one conducting wire 3 opposite to front electrode 10. Second resin member 7 covers at least a part of joining part 30, adjacent part 32, and at least a part of rising part 33. As illustrated in FIG. 19, in a top view, second resin member 7 is placed over a boundary between at least one first resin member 2 and joining part 30.

Second resin member 7 contains at least either a polyimide-based resin or a polyamide-based resin. Second resin member 7 may be made of a resin having high heat resistance. Second resin member 7 has a thixotropy index of greater than or equal to 1.1, for example. The thixotropy index of second resin member 7 may be greater than or equal to 2.5, for example.

Second resin member 7 may contain a filler (not illustrated). The filler (not illustrated) contained in second resin member 7 is made of, for example, ceramic, metal, or rubber. Second resin member 7 may have a glass transition temperature higher than the maximum allowable working temperature of semiconductor device 50. The glass transition temperature of second resin member 7 may be greater than or equal to 150° C., for example.

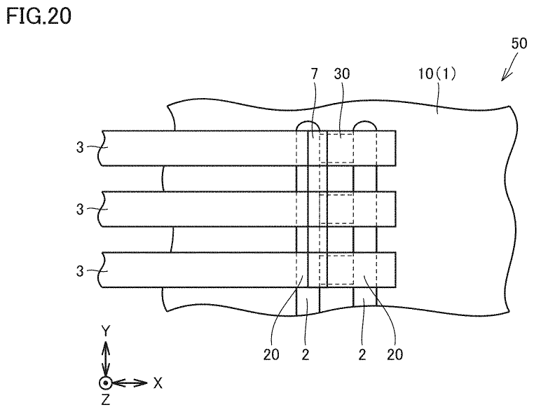

Hereinafter, a modification of the second embodiment will be described with reference to FIGS. 19 and 20. Note that, in the following description, the same or corresponding parts are denoted by the same reference numerals, and no redundant description will be given of such parts.

As illustrated in FIG. 20, according to the modification of the second embodiment, at least one conducting wire 3 includes a plurality of conducting wires 3.

Second resin member 7 extends over plurality of conducting wires 3. According to the present embodiment, second resin member 7 intersects with plurality of conducting wires 3.

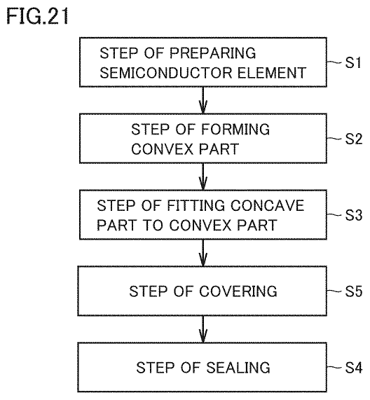

Next, a method for manufacturing semiconductor device 50 according to the second embodiment will be described with reference to FIG. 21.

As illustrated in FIG. 21, according to the present embodiment, step S5 of covering, with second resin member 7, a portion extending from rising part 33 to joining part 30 through adjacent part 32 of at least one conducting wire 3 on the side of at least one conducting wire 3 opposite to front electrode 10 is further provided.

After joining part 30, adjacent part 32, and rising part 33 are covered with second resin member 7, a solvent of second resin member 7 may be volatilized so as to temporarily harden second resin member 7. For example, second resin member 7 is temporarily hardened by being heated at 100° C. for 1 minute on a hot plate.

After step S3 of fitting concave part 31 to convex part 20, second resin member 7 is fully hardened. When the solvent of second resin member 7 is sufficiently volatilized, second resin member 7 is fully hardened. When second resin member 7 contains a polyimide-based resin, a ring closure reaction occurs in the imide precursor, so that second resin member 7 is fully hardened. In order to fully harden second resin member 7, second resin member 7 is heated, for example, at 200° C. for 3 hours in a low oxygen oven.

As illustrated in FIG. 21, after step S5 of covering with the second resin member 7, step S4 of scaling semiconductor element 1, at least one first resin member 2, second resin member 7, and conducting wire 3 in sealing resin member 4 may be further provided.

Next, actions and effects of the present embodiment will be described.

In semiconductor device 50 according to the present embodiment, as illustrated in FIG. 18, rising part 33 rises from adjacent part 32 on front electrode 10 in a direction away from body part 11. According to the present embodiment, second resin member 7 covers a portion extending from rising part 33 to joining part 30 through adjacent part 32. This allows joining part 30, adjacent part 32, and rising part 33 to be reinforced. This makes it possible to prevent, even when semiconductor device 50 is certified during the power cycle test, joining part 30, adjacent part 32, and rising part 33 from cracking. This in turn makes it possible to increase the reliability of semiconductor device 50. It is further possible to prevent at least one conducting wire 3 being broken at adjacent part 32.

Since second resin member 7 contains at least either a polyimide-based resin or a polyamide-based resin, second resin member 7 is higher in heat resistance than second resin member 7 containing neither the polyimide-based resin nor the polyamide-based resin. This makes it possible to provide semiconductor device 50 having high reliability.

Since second resin member 7 has a thixotropy index of greater than or equal to 1.1, joining part 30, adjacent part 32, and rising part 33 can be covered with second resin member 7 having a sufficient thickness. The thickness of second resin member 7 is greater than or equal to 10 μm and less than or equal to 100 μm, for example. This makes it possible to prevent joining part 30, adjacent part 32, and rising part 33 from cracking.

In semiconductor device 50 according to the modification of the present embodiment, as illustrated in FIG. 20, second resin member 7 extends over plurality of conducting wires 3. This allows, when second resin member 7 is dispensed, second resin member 7 to be continuously applied in the manufacturing process of semiconductor device 50. This in turn allows a reduction in working time taken for manufacturing semiconductor device 50.

The method for manufacturing semiconductor device 50 according to the present embodiment further includes, as illustrated in FIG. 21, after step S3 of fitting concave part 31 to convex part 20, step S5 of covering, with second resin member 7, the portion extending from rising part 33 to joining part 30 through adjacent part 32 of at least one conducting wire 3 on the side of at least one conducting wire 3 opposite to front electrode 10. This allows adjacent part 32 to be reinforced.

As illustrated in FIG. 21, after step S5 of covering with second resin member 7, step S4 of sealing semiconductor element 1, at least one first resin member 2, second resin member 7, and conducting wire 3 in sealing resin member 4 is further provided. This causes semiconductor element 1, at least one first resin member 2, second resin member 7, and conducting wire 3 to be reinforced by scaling resin member 4, allowing an increase in the reliability of semiconductor device 50.

### Third Embodiment

According to the present embodiment, the semiconductor device according to the first embodiment and the second embodiment is applied to a power conversion device. Although the present disclosure is not limited to a specific power conversion device, a structure where the present disclosure is applied to a three-phase inverter will be described below as the third embodiment.

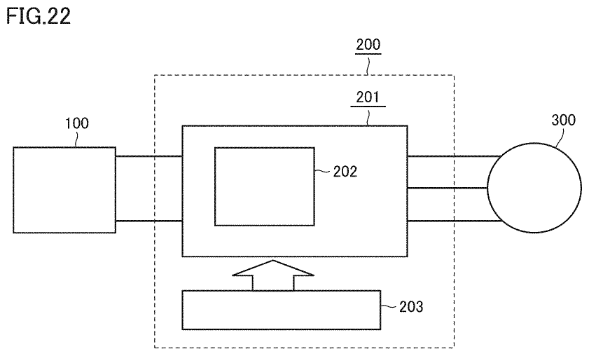

FIG. 22 is a block diagram illustrating a configuration of a power conversion system to which the power conversion device according to the present embodiment is applied.

The power conversion system illustrated in FIG. 22 includes a power supply 100, a power conversion device 200, and a load 300. Power supply 100 is a DC power supply and supplies DC power to power conversion device 200. Power supply 100 may be made up of various components such as a DC system, a solar cell, and a storage battery, or alternatively, may be made up of a rectifier circuit and AC/DC converter connected to an AC system. Further, power supply 100 may be made up of a DC/DC converter that converts DC power output from the DC system into predetermined power.

Power conversion device 200 is a three-phase inverter connected between power supply 100 and load 300, converts DC power supplied from power supply 100 into AC power, and supplies the AC power to load 300. As illustrated in FIG. 22, power conversion device 200 includes a main conversion circuit 201 that converts DC power into AC power and outputs the AC power, and a control circuit 203 that outputs, to main conversion circuit 201, a control signal for controlling main conversion circuit 201.

Load 300 is a three-phase electric motor driven by the AC power supplied from power conversion device 200. Note that load 300 is not limited to a specific application, and is an electric motor mounted on various electric devices such as a hybrid vehicle, an electric vehicle, a railroad car, an elevator, and an air conditioner.

A description will be given below of details of power conversion device 200. Main conversion circuit 201 includes a switching element and a freewheeling diode (not illustrated), converts DC power supplied from power supply 100 into AC power by switching the switching element, and supplies the AC power to load 300. Although there are various specific circuit structures applicable to main conversion circuit 201, main conversion circuit 201 according to the present embodiment is a two-level three-phase full bridge circuit and may be made up of six switching elements and six freewheeling diodes each being in anti-parallel to a corresponding one of the switching elements. At least either each switching element or each freewheeling diode of main conversion circuit 201 is a switching element or a freewheeling diode included in a semiconductor device 202 corresponding to either the semiconductor device according to the first embodiment or the semiconductor device according to the second embodiment. Each two switching elements of the six switching elements are connected in series to constitute upper and lower arms, and each of the upper and lower arms constitutes a corresponding phase (U-phase, V-phase, W-phase) of the full bridge circuit. Then, output terminals of the upper and lower arms, that is, three output terminals of main conversion circuit 201, are connected to load 300.

Further, main conversion circuit 201 includes a drive circuit (not illustrated) that drives each switching element, but the drive circuit may be built in semiconductor device 202 or may be separate from semiconductor device 202. The drive circuit generates a drive signal to drive each switching element of main conversion circuit 201 and supplies the drive signal to a control electrode of the switching element of main conversion circuit 201. Specifically, in accordance with the control signal from control circuit 203 to be described later, a drive signal to switch the switching element to the ON state or a drive signal to switch the switching element to the OFF state is output to the control electrode of each switching element. When the switching element is kept in the ON state, the drive signal is a voltage signal (ON signal) greater than or equal to a threshold voltage of the switching element, and when the switching element is kept in the OFF state, the drive signal is a voltage signal (OFF signal) less than or equal to the threshold voltage of the switching element.

Control circuit 203 controls each switching element of main conversion circuit 201 so as to supply desired power to load 300. Specifically, a time (ON time) during which each switching element of main conversion circuit 201 is in the ON state is calculated based on the power to be supplied to load 300. For example, main conversion circuit 201 can be controlled by PWM control under which the ON time of the switching element is modulated in a manner that depends on the voltage to be output. Then, a control command (control signal) is output to the drive circuit contained in main conversion circuit 201 so as to output the ON signal to a switching element to be in the ON state and output the OFF signal to a switching element to be in the OFF state at each time point. The drive circuit outputs the ON signal or the OFF signal as the drive signal to the control electrode of each switching element in accordance with the control signal.

In the power conversion device according to the present embodiment, the semiconductor device according to the first embodiment and the second embodiment is applied as semiconductor device 202 that is a component of main conversion circuit 201, so that it is possible to implement a power conversion device having high reliability and a simple structure.

For the present embodiment, an example where the present disclosure is applied to a two-level three-phase inverter has been described, but the present disclosure is not limited to such an example, and may be applied to various power conversion devices. According to the present embodiment, a two-level power conversion device is used, but a three-level or multi-level power conversion device may be used, or alternatively, the present disclosure may be applied to a single-phase inverter in a case where power is supplied to a single-phase load. Further, in a case where power is supplied to a DC load or the like, the present disclosure may also be applied to a DC/DC converter, an AC/DC converter, or the like.

Further, the power conversion device to which the present disclosure is applied is not limited to a power conversion device applied to a case where the above-described load is an electric motor, and may be used as a power supply device applied to, for example, an electric discharge machine, a laser beam machine, an induction heating cooker, or a non-contact power supply system. Alternatively, the power conversion device may be used as a power conditioner applied to a photovoltaic system, a power storage system, or the like.

It should be understood that the embodiments disclosed herein are illustrative in all respects and not restrictive. The scope of the present invention is defined by the claims rather than the above description and is intended to include the claims, equivalents of the claims, and all modifications within the scope.

### REFERENCE SIGNS LIST

1: semiconductor element, 2: first resin member, 3: wire, 4: second resin member, 7: third resin, 10: front electrode, 10t: first surface, 10b: second surface, 11: body part, 20: convex part, 30: joining part, 31: concave part, 32: rising part, 33: rising part, 50: semiconductor device, 100: power supply, 200: power conversion device, 201: main conversion circuit, 202: semiconductor device, 203: control circuit, 300: load

1. A semiconductor device comprising:
a semiconductor element including a body part and a front electrode having a first surface bonded to the body part and a second surface on an opposite side of the first surface;
at least one first resin member disposed on the second surface of the front electrode; and
at least one conducting wire including a joining part adjacent to the at least one first resin member and bonded to the second surface, wherein
the at least one first resin member includes a convex part protruding from the front electrode in a direction away from the body part,
the at least one conducting wire includes a concave part adjacent to the joining part and extending along the convex part, and
the concave part is fitted to the convex part.

2. The semiconductor device according to claim 1, wherein the at least one first resin member has a viscosity of greater than or equal to 50 Pa·s and less than or equal to 150 Pa·s.

3. The semiconductor device according to claim 1, wherein
with a direction in which the first surface and the second surface are positioned on opposite sides of the front electrode defined as a first direction, a direction from the joining part toward the concave part along the second surface defined as a second direction, and a direction orthogonal to both the first direction and the second direction defined as a third direction,
a dimension of the at least one first resin member in the first direction is 0.2 times or more and less than 1 time a dimension of the at least one conducting wire in the first direction at a portion where the joining part is provided, and
a dimension of the at least one first resin member in the second direction is 0.5 times or more and 10 times or less a dimension of the joining part in the third direction.

4. The semiconductor device according to claim 1, wherein the at least one first resin member contains at least either a polyimide-based resin or a polyamide-based resin.

5. The semiconductor device according to claim 1, wherein the at least one first resin member has a thixotropy index of greater than or equal to 1.1.

6. The semiconductor device according to claim 1, further comprising a second resin member, wherein
the at least one conducting wire includes an adjacent part adjacent to the joining part and a rising part rising from the adjacent part on the front electrode in a direction away from the body part, and
the second resin member covers a portion extending from the rising part to the joining part through the adjacent part on a side of the at least one conducting wire opposite to the front electrode.

7. The semiconductor device according to claim 6, wherein the second resin member contains at least either a polyimide-based resin or a polyamide-based resin.

8. The semiconductor device according to claim 6, wherein the second resin member has a thixotropy index of greater than or equal to 1.1.

9. The semiconductor device according to claim 1, wherein
the at least one conducting wire includes a plurality of conducting wires, and
the concave part of each of the plurality of conducting wires is fitted to the convex part.

10. The semiconductor device according to claim 6, wherein
the at least one conducting wire includes a plurality of conducting wires, and
the second resin member extends over the plurality of conducting wires.

11. A power conversion device comprising:
a main conversion circuit including the semiconductor device according to claim 1, the main conversion circuit to convert input power and output the converted power; and
a control circuit to output, to the main conversion circuit, a control signal for controlling the main conversion circuit.

12. A method for manufacturing a semiconductor device, comprising:
preparing a semiconductor element including a body part and a front electrode having a first surface bonded to the body part and a second surface on an opposite side of the first surface;
forming a convex part on at least one first resin member by applying the at least one first resin member to the second surface of the front electrode, the convex part protruding from the front electrode in a direction away from the body part; and
bonding a joining part of at least one conducting wire to the second surface of the front electrode so as to make the joining part adjacent to the at least one first resin member, forming a concave part extending along the convex part adjacent to the joining part, and fitting the concave part to the convex part.

13. The method for manufacturing a semiconductor device according to claim 12, wherein in the forming a convex part, the at least one first resin member is temporarily hardened so as to keep the convex part of the at least one first resin member.

14. The method for manufacturing a semiconductor device according to claim 12, further comprising sealing the semiconductor element, the at least one first resin member, and the at least one conducting wire in a sealing resin member after the fitting the concave part to the convex part.

15. The method for manufacturing a semiconductor device according to claim 12, wherein
the at least one conducting wire includes an adjacent part adjacent to the joining part and a rising part rising from the adjacent part on the front electrode in a direction away from the body part,
the method further comprising covering, with a second resin member, a portion of the at least one conducting wire extending from the rising part to the joining part through the adjacent part on a side of the at least one conducting wire opposite to the front electrode.

16. The method for manufacturing a semiconductor device according to claim 15, further comprising sealing the semiconductor element, the at least one first resin member, the second resin member, and the at least one conducting wire in an sealing resin member after the covering with the second resin member.
